(19) United States
(12) Patent Application Publication
(10) Pub. No.: US 2008/0043442 A1
(43) Pub. Date: Feb. 21, 2008

(54) COMPUTER SYSTEM WITH THERMAL CONDUCTION

(76) Inventors: Travis C. Strickland, Houston, TX (US); Matthew F. Brantley, Houston, TX (US); John C. Garza, Houston, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/465,022

(22) Filed: Aug. 16, 2006

(51) Int. Cl. H05K 7/20

(52) U.S. Cl. 361/709

(57) ABSTRACT

A computer system comprising a computer chassis supporting at least one electronic component, a rack chassis supporting the computer chassis, a heat sink disposed between said computer chassis and said rack chassis, and wherein said heat sink is thermally coupled to said computer chassis and to said rack chassis such that heat is conducted between said computer chassis, said heat sink, and said rack chassis.

### BACKGROUND

Computer systems include numerous electrical components that draw electrical current to perform their intended functions. For example, a computer's microprocessor or central processing unit (“CPU”) requires electrical current to perform many functions such as controlling the overall operations of the computer system and performing various numerical calculations. Generally, any electrical device through which electrical current flows produces heat. The amount of heat any one device generates generally is a function of the amount of current flowing through the device.

Typically, an electrical device is designed to operate correctly within a predetermined temperature range. If the temperature exceeds the predetermined range (i.e., the device becomes too hot or too cold), the device may not function correctly, thereby potentially degrading the overall performance of the computer system. Thus, many computer systems include cooling systems to regulate the temperature of their electrical components. Air-cooled systems often utilize an array of fans to move air from the environment, through a computer enclosure, and back to the environment. As the air passes through the enclosure it comes in thermal contact with, and absorbs heat from, the heat-generating components within the enclosure. The heat transfer rate that can be achieved by an air-cooled system is a function of the volume of air that can be moved through the enclosure and the temperature of that air.

Many computer systems and components, such as servers, routers, and storage arrays, are configured for mounting in rack enclosures that allow for efficient storage of multiple components. Many rack enclosures are essentially large cabinets into which a plurality of components are mounted. These racks are often designed for densely storing a multitude of components while allowing for easy access to the components for upgrading and maintenance. It is not unusual to find a number of racks co-located in a server farm, or other large grouping of components.

Computer system designs, such as rack-mounted servers, that seek to increase computational power while reducing the size of computer equipment create many challenges with controlling the temperature within these ‘dense’ computer systems. Increasing the computational power of computer systems often results in the utilization of high power components that generate high levels of heat. Also, increasing the computational power of computer systems results in increasing the footprint of the heat-generating components while maintaining the same storage volume and air flow heat transfer capacity. Reducing the size of the computer system often involves packaging components in close proximity to each other, therefore restricting airflow through the systems. The combination of high power, high heat-generating components and compact design is pushing the limits of current air-cooled systems.

### SUMMARY

A computer system comprising a computer chassis supporting at least one electronic component, a rack chassis supporting the computer chassis, a heat sink disposed between said computer chassis and said rack chassis, and wherein said heat sink is thermally coupled to said computer chassis and to said rack chassis such that heat is conducted between said computer chassis, said heat sink, and said rack chassis.

### BRIEF DESCRIPTION OF THE DRAWINGS

For a detailed description of exemplary embodiments of the invention, reference will now be made to the accompanying drawings in which:

FIG. 1 shows an array of computer systems and rack constructed in accordance with embodiments of the invention;

FIG. 2 shows a computer system and rack;

FIG. 3 shows a computer system and rack constructed in accordance with embodiments of the invention;

FIG. 4 shows a partial top view of the computer system and rack of FIG. 3;

FIG. 5 shows thermal couplings constructed in accordance with embodiments of the invention;

FIG. 6 shows thermal couplings constructed in accordance with embodiments of the invention;

FIG. 7 shows a side view of thermal couplings constructed in accordance with embodiments of the invention;

FIG. 8 shows a side view of thermal couplings constructed in accordance with embodiments of the invention;

FIG. 9 shows a side view of thermal couplings constructed in accordance with embodiments of the invention; and

FIG. 10 shows a side view of thermal couplings constructed in accordance with embodiments of the invention.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections.,

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

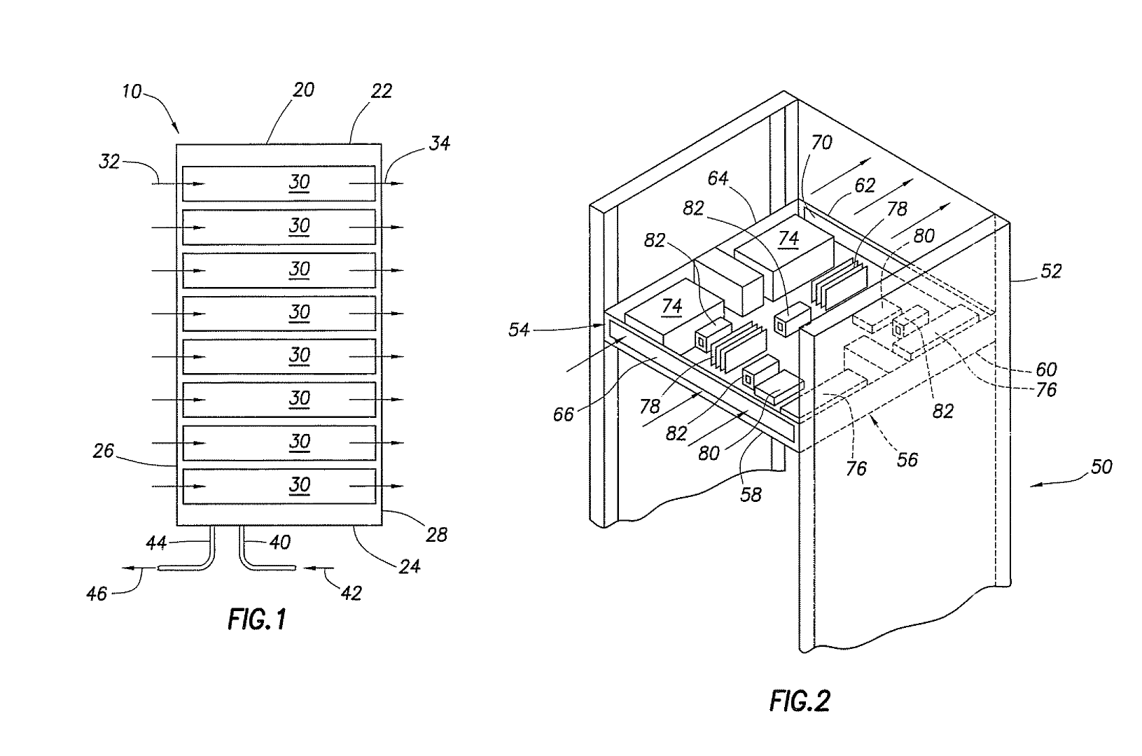

Referring to FIG. 1, a computer system 10 comprises rack chassis or frame 20 having top end 22, bottom end 24, front end 26, and back end 28. Rack chassis 20 supports a plurality of computer components 30. In an exemplary air flow configuration, air 32 from the environment is drawn into each computer component 30. The air removes heat from electronic components within computer component and exhausts air 34 back to the environment.

Computer component 30 may be any number of devices, including a computer or server. Referring to FIG. 2, a server system 50 comprises rack 52 supporting computer system 54. Computer system 54 comprises chassis 56 having front end 58, back end 62, and sides 60, 64. Inlet 66 is disposed through front end 58 and outlet 70 is disposed through back end 62. Computer system 54 comprises numerous electronic components including hard drives 74, power supplies 76, memory modules 78, and processors 80. By way of example, computer system 54 of FIG. 2 further comprises air movers 82, but air movers are not necessary to all embodiments in accordance with the invention. Chassis 56 is slidingly engaged with rack 52 via sliding means such as rails disposed adjacent sides 60, 64.

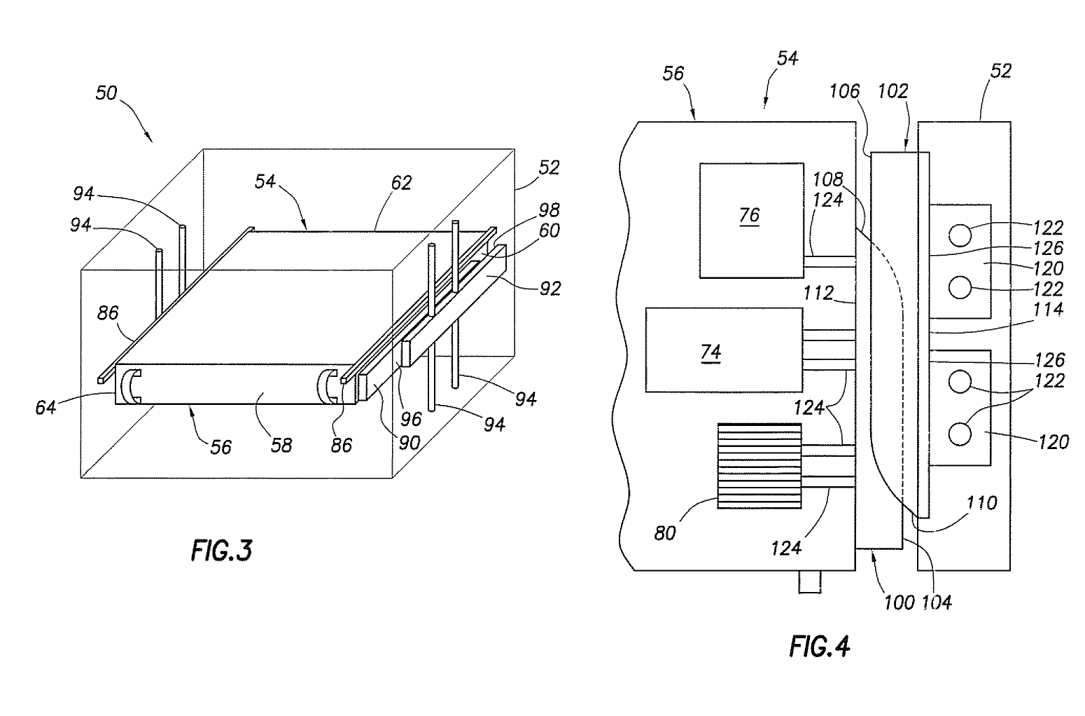

Referring now to FIG. 3, another view of server system 50 is shown. Rail assemblies 86 mounted to the inside of rack 52 allow computer system 54 to be removed and replaced by a sliding action; rail assemblies 86 support computer system 54 adjacent sides 60, 64 when computer 54 is in position in rack 52. Computer chassis 56 further comprises thermal coupling 90 mounted to sides 60, 64 just below rail assemblies 86. A counterpart thermal coupling 92 is mounted to the inside of rack 52 such that couplings 90, 92 are in thermal communication when computer chassis 56 slides into place. In alternative embodiments of the invention, couplings 90, 92 may be mounted in other locations such that they engage each other for thermal contact when computer 54 is installed. Fluid conduits 94 are supported by rack chassis 52 and extend through coupling 92 such that fluid conduits thermally communicate with coupling 92. Fluid conduits 94 may carry water, for example, or refrigerant, or any other liquid coolant.

Coupling faces 96, 98 of couplings 90, 92, respectively, are shown as flat surfaces in FIG. 3. Coupling faces 96, 98 create a flat surface on flat surface thermal conduction relationship between couplings 90, 92. The thermal conduction relationship between couplings 90, 92 is not limited to flat surfaces, and other exemplary embodiments of thermal conduction relationships will be described herein.

Couplings 90, 92 are constructed such that they operate as heat sinks. For example, couplings 90, 92 comprise aluminum, copper, alloys thereof or any other lightweight material having significant thermal conductivity. They are also constructed with appropriate dimensions for appreciable heat conduction. Thus, the heat sinks of couplings 90, 92 conduct significant amounts of heat, as opposed to other components of computer 54 which conduct only limited or negligible quantities of heat. Other components of computer 54, such as internal metallic components, chassis 56, or rail assemblies 86, may include conductive metals, but do not function as heat sinks because they are not capable of conducting significant amounts of heat necessary for computer system cooling. When mated, couplings 90, 92 combine to form a larger heat sink than the individual heat sinks of couplings 90, 92.

Still referring to FIG. 3, heat that is collected in thermal coupling 92 is carried away by water flowing through fluid conduits 94. Fluid conduits 94 communicate with a fluid delivery system in rack 52 (not shown). Referring briefly to FIG. 1, cooled water from source 42 is brought into rack 22 through inlet 40 at the bottom of rack 22 and delivered to the various thermal couplings in rack 22. Heat is transferred from the couplings to the water, and the heated water is exhausted from rack 22 through outlet 44 to a cooling system 46.

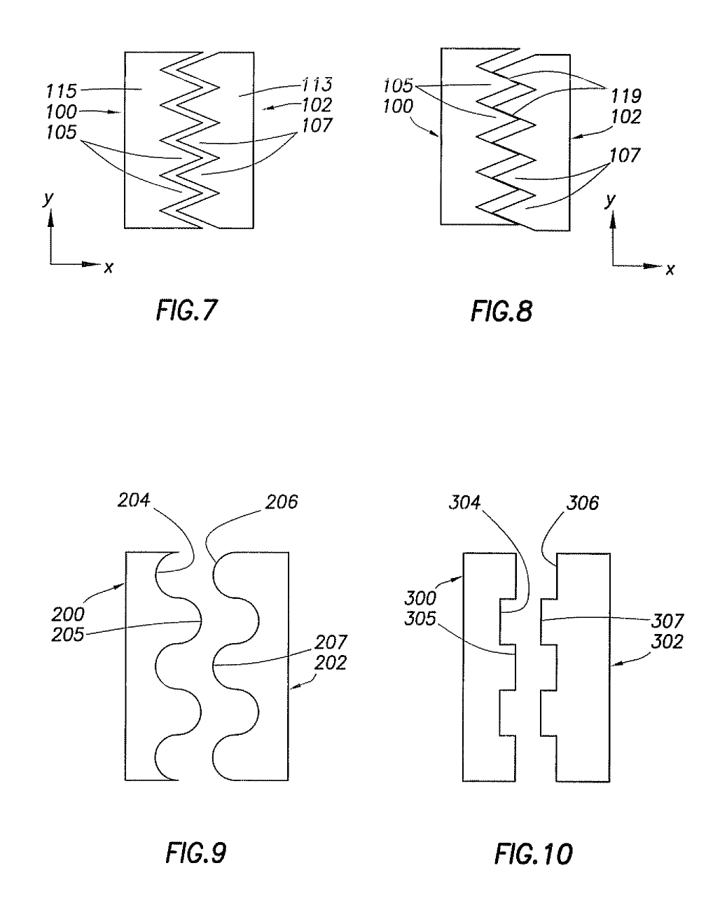

Referring to FIG. 4, computer chassis 56 and rack chassis 52 are thermally connected by couplings 100, 102. Unlike the flat surface to flat surface relationship of thermal couplings 90, 92, couplings 100, 102 comprise an alternative interlocking, overlapping, or mating relationship. The interlocking, mating relationship of couplings 100, 102 is further shown in FIGS. 5-7. As shown in FIG. 5, coupling 100 comprises top end 103, sides 111, 115, and a plurality of ridges or teeth 105 on face 104. Each of ridges 105 comprises reduced or curved portion 108. Coupling 102 comprises top end 109, sides 113, 117, and a plurality of ridges or teeth 107 on face 106. Each of ridges 107 comprises reduced or curved portion 110. Couplings 100, 102 are adapted to be heat sinks, as previously described with respect to couplings 90, 92. In FIG. 7, the interlocking relationship of couplings 100, 102 is shown in a side view. Ridges 105 mate with ridges 107 to form an even larger heat sink.

An interlocking relationship between the thermally conductive surfaces of the couplings provides stability to the thermal coupling, an increased surface area for thermal conduction, and self-alignment of the couplings as they slidingly engage each other. As seen in FIG. 5, faces 104, 106 of couplings 100, 102, respectively, comprise a series of ridges 105, 107. The ridges create a saw-tooth shape as seen in the profile side view of FIG. 7. To bring the couplings 100, 102 into the mating relationship shown in FIG. 7, server coupling 100 must slide into rack coupling 102 as computer system 54 slides into rail assemblies 86 of rack 52. In alternative embodiments of the invention, rails assemblies 86 are not included as couplings 100, 102 also act as the supporting rail assemblies

Referring back to FIG. 4, computer system 54 and chassis 56 support hard drive 74, power supply 76, and processor 80. Heat conductors 124 couple each of hard drive 74, power supply 76, and processor 80 to back surface 112 of coupling 100. Heat conductors 124 extend from the back of coupling 100 and into chassis 56 such that heat conductors 124 are thermally coupled to the several computer components and thermal coupling 100. Heat conductors 124 comprise heat pipes, for example, that are capable of moving heat from one location to another, most notably, between conductive surfaces having different temperatures.

Still with reference to FIG. 4, rack chassis 52 comprises heat exchangers 120 mounted within the chassis enclosure. Contact surfaces 126 of heat exchangers 120 are disposed adjacent and in contact with back surface 114 of coupling 102. A robust contact between surfaces 126 and surface 114 ensures proper thermal conduction between heat exchangers 120 and coupling 102, thus coupling 102 may be mounted or otherwise securely attached to heat exchangers 120. Heat exchangers 120 comprise fluid conduits 122 for carrying water or other cooled liquid. The arrangement causes heat exchangers 120 to be thermally coupled to coupling 102 such that heat is removed from coupling 102 by conduction to heat exchanger 120. Fluid conduits 122 communicate with liquid delivery and exhaust lines, such as delivery line 40 and exhaust line 44 of rack 20 in FIG. 1, so that cool water is brought continuously through heat exchangers 120 and exhausted therefrom as needed. Other examples of heat exchangers may be developed by persons of ordinary skill in the art with reference to the teachings of this disclosure.

To facilitate engagement of couplings 100, 102 as computer 54 slides into place, lead portions 111, 113, respectively, comprise reduced or curved portions 108, 110 of ridges 105, 107. As lead portion 111 advances toward lead portion 113 in the Z-direction, reduced portion 108 allows greater tolerance for misalignment in the Y-direction with reduced portion 110. As reduced portion 108 engages reduced portion 110 misaligned couplings 100, 102 are forced into alignment as coupling 100 advances further relative to coupling 102 and full ridge portions 105, 107, respectively, are engaged. During the advancement of coupling 100, the tolerances between ridges 105, 107 are reduced and thermal contact is maximized. Therefore, couplings 100, 102 comprise a self-alignment feature such that the couplings are disposed as shown in FIG. 4 (top view) and FIG. 7 (side view) when fully engaged (the gap shown in FIG. 7 is for clarity purposes only, and does not represent an actual gap between couplings 100, 102 as they are in contact for thermal conduction).

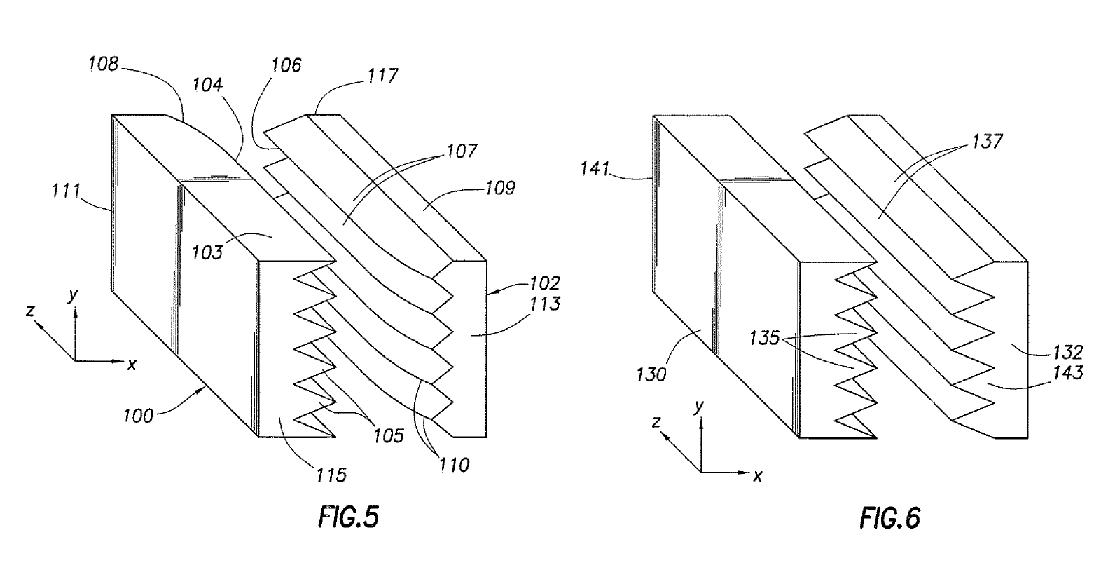

In contrast, FIG. 6 shows exemplary embodiments of couplings 130, 132 that do not have reduced ridge portions 108, 110. Lead portions 141, 143 require greater alignment in the Y-direction for proper sliding engagement of couplings 130, 132 such that lead portion 141 does not interfere with lead portion 143 as coupling 130 advances toward coupling 132 in the Z-direction.

In addition to the self-alignment feature of the couplings, the interlocking relationship of the couplings provides increased stability of the contact between the couplings as opposed to contact between flat surfaces, for example, as flat surfaces tend to move more easily relative to each other. Further, movement in the X-direction of FIG. 7, due to tolerances in rack chassis 52, computer chassis 56, and rail assembly 86, would cause flat surfaces to lose contact. As shown in FIG. 8, movement in the X-direction between couplings 100, 102 may cause couplings to move apart relative to each other, but remain in significant thermal contact at surfaces 119. As coupling 102 moves slightly away from coupling 100, gravity or other forces in computer system 10 will force couplings 100, 102 into contact at surfaces 119.

Further exemplary embodiments of the couplings are shown in FIGS. 9 and 10. Referring to FIG. 9, couplings 200, 202 comprise faces 204, 206, respectively, having ridges 205, 207 forming mating curved or sinusoidal shapes Referring to FIG. 10, couplings 300, 302 comprise faces 304, 306, respectively, having ridges 305, 307 forming mating square or block shapes The couplings of FIGS. 9 and 10 may also comprise the self-alignment features previously described. The coupling faces of FIGS. 4-10 comprise profile shapes that increase the thermal contact surface area over a flat surface. Further, the mating relationship between two coupling faces in accordance with the exemplary embodiments described herein will maintain significant thermal contact despite an imperfect fit. Other examples of mating shapes for the coupling faces may be developed by persons of ordinary skill in the art with reference to the teachings of this disclosure.

The components of the thermal conduction cooling system described herein are considered substantially independent of air moving or cooling devices, such as air movers 82. The exemplary embodiments of the invention described herein do not depend on air flow, or convection, to move heat from the heat-generating components of a computer system. Thus, the thermal conduction cooling system described herein may be used to supplement an air moving or cooling system, or supplant such a system such that no fluid is moved through the computer system for cooling purposes. The thermal conduction cooling system described herein does not require air movers, potentially reducing the complexity, space, and noise needed to cool a computer system, and also focusing the heat transfer on a smaller volume of hardware as opposed to a larger volume of air. Further, heat conductors 124 thermally couple components internal to computer chassis 56 to coupling 100 external of chassis 56. Thus, it is not necessary for the cooled liquid to exit rack chassis 52, or for any fluid, including air, to enter computer chassis 56. Communicating a liquid out of rack-chassis 52 and into computer chassis 56 is an awkward and cumbersome process, and increases the risk of exposing sensitive computer components to hazardous liquids.

The above discussion is meant to be illustrative of the principles and various embodiments of the present invention. Numerous variations and modifications will become apparent to those skilled in the art once the above disclosure is fully appreciated. For example, embodiments of the invention may or may not include air movers as the thermal conduction of the invention is independent of air movement. Further, the interface between the thermal couplings comprises various shapes, for example. It is intended that the following claims be interpreted to embrace all such variations and modifications.

What is claimed is:

1. A computer system, comprising:
a computer chassis supporting at least one electronic component;
a rack chassis supporting said computer chassis;
a heat sink disposed between said computer chassis and said rack chassis; and
wherein said heat sink is thermally coupled to said computer chassis and to said rack chassis such that heat is conducted between said computer chassis, said heat sink, and said rack chassis.

2. The computer system of claim 1 wherein said heat sink further comprises a first thermal coupling having a first heat sink thermally coupled to a second thermal coupling having a second heat sink.

3. The computer system of claim 1 further comprising a heat exchanger supported by said rack chassis and thermally coupled to said heat sink.

4. The computer system of claim 3 wherein said heat exchanger further comprises a fluid conduit and a cooled liquid disposed in said fluid conduit.

5. The computer system of claim 4 wherein said fluid conduit receives said cooled liquid from a rack chassis inlet connected to a fluid source and said fluid conduit communicates heated liquid to a rack chassis outlet connected to an exhaust.

6. The computer system of claim 1 further comprising a heat conductor that extends into said computer chassis from said heat sink, wherein said heat conductor is thermally coupled to said heat sink and said electronic component

7. The computer system of claim 6 wherein said heat conductor is a heat pipe.

8. The computer system of claim 1 wherein said electronic component comprises at least one of a processor, a hard drive, and a power supply.

9. The computer system of claim 2 wherein said first thermal coupling is in an interlocked, mating relationship with said second thermal coupling.

10. The computer system of claim 2 wherein said first and second thermal couplings comprise faces each having a plurality of ridges.

11. The computer system of claim 10 wherein said plurality of ridges comprises a profile having any one of a saw-tooth shape, a sinusoidal shape, and a square shape.

12. The computer system of claim 10 wherein said plurality of ridges comprises means for self-aligning said first and second thermal couplings.

13. A computer system, comprising:
a computer chassis having a volume and supporting at least one electronic component;
a rack chassis removably supporting said computer chassis, said rack chassis including a heat exchanger; and
means for cooling said computer chassis volume by conducting a significant amount of the heat in said chassis volume to said heat exchanger without communicating a fluid into said chassis volume.

14. The computer system of claim 13 wherein said cooling means further comprises a heat sink thermally coupling said computer chassis and said rack chassis.

15. The computer system of claim 13 further comprising means for conducting a significant amount of the heat in said electronic component to a location external of said computer chassis.

16. A computer system, comprising:
a computer chassis supporting at least one electronic component;
a heat sink mounted to an exterior of said computer chassis; and
a heat conductor that extends into said computer chassis from said heat sink, wherein said heat conductor is thermally coupled to said heat sink and to said electronic component.

17. The computer system of claim 16 wherein said heat sink comprises a first thermal coupling adapted to receive a second thermal coupling.

18. The computer system of claim 17 further comprising means for self-aligning said first and second thermal couplings.

19. The computer system of claim 16 wherein said heat conductor is a heat pipe.

20. The computer system of claim 16 further comprising a support apparatus adapted to support said computer chassis and conduct heat away from said heat sink.
